(19) United States
(12) Patent Application Publication
(10) Pub. No.: US 2007/0195346 A1
(43) Pub. Date: Aug. 23, 2007

(54) Apparatus, method, and program product for color correction

(75) Inventor: Kazuhiro Fuji, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/708,052

(22) Filed: Feb. 20, 2007

(30) Foreign Application Priority Data
Feb. 23, 2006 (JP) 2006-047033

(51) Int. Cl. G03F 3/08

(52) U.S. Cl. 358/1.9; 358/518

(57) ABSTRACT

A color correction apparatus of this invention includes a correction unit to correct a color of an input pixel having a color included in a particular region of a color space, and a correction amount calculator to change an amount of the color correction in a nonlinear manner in an order of colors disposed from inside the particular region to a boundary. The correction amount calculator gradually decreases the color correction amount from inside the particular region to the boundary, so that the correction amount decreases to 0 at the boundary.

### BACKGROUND OF THE INVENTION

1. Field of the Invention

The present invention relates to an apparatus, a method, and a program product for color correction, and particularly to an apparatus, a method, and a program product for color correction to correct color of an input pixel of a color included in a particular region of the color space.

2. Description of Related Art

A color correction apparatus is known for specifying a target color to be corrected and a correction color used to correct the target color to the correction color for each pixel of an input image. For example the technique disclosed in Japanese Unexamined Patent Application Publication No. 10-198795 calculates an approximation hx that indicates a degree of approximation of an input pixel to the target color and the correction amount by multiplying the approximation hx and a correction coefficient so as to correct the color by adding the correction amount to the input pixel.

FIG. 20 is a block diagram showing the configuration of an approximation calculator 900 for calculating the approximation hx in a conventional color correction apparatus. As shown in FIG. 20, the conventional approximation calculator 900 includes a target color component extractor 901 for extracting color components (r0′, g0′, b0′) of a target color (r0, g0, b0), a target color component storage unit 902 for storing the color components of the target color, an input color component extractor 903 for extracting color components (r′, g′, b′) of input pixel (r, g, b), and an hx output unit 905 for calculating the approximation hx from D value and outputting the approximation. Further, the hx output unit 905 includes a multiplier 906 for multiplying the D value and a weight mul, and an hx calculator 907 for calculating the approximation hx according to the result of multiplication by the multiplier 906. A color distance is a distance between colors in a color space including RGB and HSV. A range of the RGB value in this document is 0<=R, G, B<=1.0.

The flowchart of FIG. 21 shows a calculation method of the approximation hx by the conventional approximation calculator 900. Firstly the target color (r0, g0, b0) and the weight mul are specified to the approximation calculator 900 (S901). Then the color components (r0′, g0′, b0′) of the target color removed with white color component are calculated and the color components are stored to the target color component storage unit (S902). After that the input color component extractor 903 calculates the color components (r′, g′, b′) of the input pixel (r, g, b) (S903). Then the D value calculator 904 calculates the color distance D from the color components (r0′, g0′, b0′) of the target color and the color components (r, g, b) of the input pixel (S904).

After that the hx output unit 905 calculates the approximation hx by a linear function including the D value and the weight mul using the multiplier 906 and the hx calculator 907 (S905). Specifically the approximation hx is calculated by the formula 1 below.

hx=1.0−mul*D (Formula 1)

Then the hx calculator 907 evaluates whether the approximation is smaller than 0 (S906). If the approximation is smaller than 0, the approximation hx=0 (S907)

FIG. 22 is an image of the approximation hx (approximation characteristic) to the color distance from the target color calculated by the conventional approximation calculator 900. As the correction amount is calculated by multiplying the approximation hx and the correction coefficient, the color is corrected by the correction amount corresponding to the approximation characteristic.

An approximation characteristic 910 is a characteristic calculated from the above formula 1. Specifically, the approximation characteristic 910 is a characteristic extending with its center at the approximation hx=1.0 of the target color, the approximation decreasing to 0 as the color distance to the target color increases. A range surrounded by boundary contacting the color distance (horizontal) axis of hx=0 is the correction range. A range distant to the correction range is non-correction range. In the approximation characteristic 910, the approximation hx decreases at a slope defined by “−mul*D” as it gets away from the target color. Specifically the approximation characteristic 910 decreases at a constant trend that is defined by the linear function, which is the formula 1.

As described in the foregoing, with the conventional color correction apparatus, the approximation for calculating the correction amount is calculated by one linear function. Thus the correction amount decreases at a constant trend as it gets away from the target color. In such case, it has now been discovered that if the coefficient such as a weight mul is increased to narrow the correction range and to make the slope steeper, the correction amount changes suddenly near the boundary between the correction and non-correction ranges. As the color largely changes near the boundary of the correction range, the change in the color is visibly distinct, thereby generating contouring.

### SUMMARY OF THE INVENTION

According to an aspect of the present invention, there is provided a color correction apparatus that comprises a correction unit to correct a color of an input pixel having a color included in a particular region of a color space, and a correction amount calculator to change an amount of the color correction in a nonlinear manner in an order of colors disposed from inside the particular region to a boundary. With this color correction apparatus, it is possible to suppress the correction amount near the boundary of the correction range, thereby suppressing the color change near the boundary of the correction range and also to prevent from generating contouring.

According to another aspect of the present invention, there is provided a method for color correction to correct a color of an input pixel having a color included in a particular region of a color space. The method includes changing an amount of the color correction in a nonlinear manner in an order of colors disposed from inside the particular region to the boundary. With this method for color correction, it is possible to suppress the correction amount near the boundary of the correction range, thereby suppressing the color change near the boundary of the correction range and also to prevent from generating contouring.

According to another aspect of the present invention, there is provided a program product for executing a color correction process by a computer to correct a color of an input pixel having a color included in a particular region of a color space. The program product includes changing an amount of the color correction in a nonlinear manner in an order of colors disposed from inside the particular region to the boundary. With this program product, it is possible to suppress the correction amount near the boundary of the correction range, thereby suppressing the color change near the boundary of the correction range and also to prevent from generating contouring.

The present invention provides an apparatus, a method, and a program product for color correction that suppresses to change the color near the boundary of the correction range and also generating contouring.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing a configuration of a color correction apparatus according to the present invention;

FIG. 2 is a block diagram showing a configuration of an approximation calculator according to the present invention;

FIG. 3 is a flowchart showing an approximation calculation method according to the present invention;

FIG. 4 is a view showing RGB color space used in the approximation calculation method according to the present invention;

FIG. 5 is an image diagram showing the RGB color space used in the approximation calculation method according to the present invention;

FIG. 6 is an image diagram showing the RGB color space used in the approximation calculation method according to the present invention;

FIG. 7 is an image diagram showing an approximation characteristic obtained by the approximation calculation method according to the present invention;

FIG. 8 is a block diagram showing a configuration of the approximation calculator according to the present invention;

FIG. 9 is a flowchart showing the approximation calculation method according to the present invention;

FIG. 10 is an image diagram showing the approximation characteristic obtained by the approximation calculation method according to the present invention;

FIG. 11 is a flowchart showing the approximation calculation method according to the present invention;

FIG. 12 is an image diagram showing the approximation characteristic obtained by the approximation calculation method according to the present invention;

FIG. 13 is a block diagram showing a configuration of the approximation calculator according to the present invention;

FIG. 14 is a flowchart showing the approximation calculation method according to the present invention;

FIG. 15 is an image diagram showing the approximation characteristic obtained by the approximation calculation method according to the present invention;

FIG. 16 a block diagram showing the configuration of the approximation calculator according to the present invention;

FIG. 17 is a flowchart showing the approximation calculation method according to the present invention;

FIG. 18 is a view showing an HSV color space used in the approximation calculation method according to the present invention;

FIG. 19 is a hardware configuration diagram of the color correction apparatus according to the present invention;

FIG. 20 is a block diagram showing a configuration of an approximation calculator according to a conventional technique;

FIG. 21 is a flowchart showing an approximation calculation method according to a conventional technique; and

FIG. 22 is an image diagram showing an approximation characteristic obtained by the approximation calculation method according to a conventional technique.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

A color correction apparatus according to a first embodiment of the present invention is described hereinafter in detail. The color correction apparatus of this embodiment is able to select any region in the correction range to change the color of the region only, and also specify the correction amount of the color in the region. In this embodiment, two linear functions are used to calculate the approximation by a RGB format, as an example to reduce the correction amount near the boundary of the correction range.

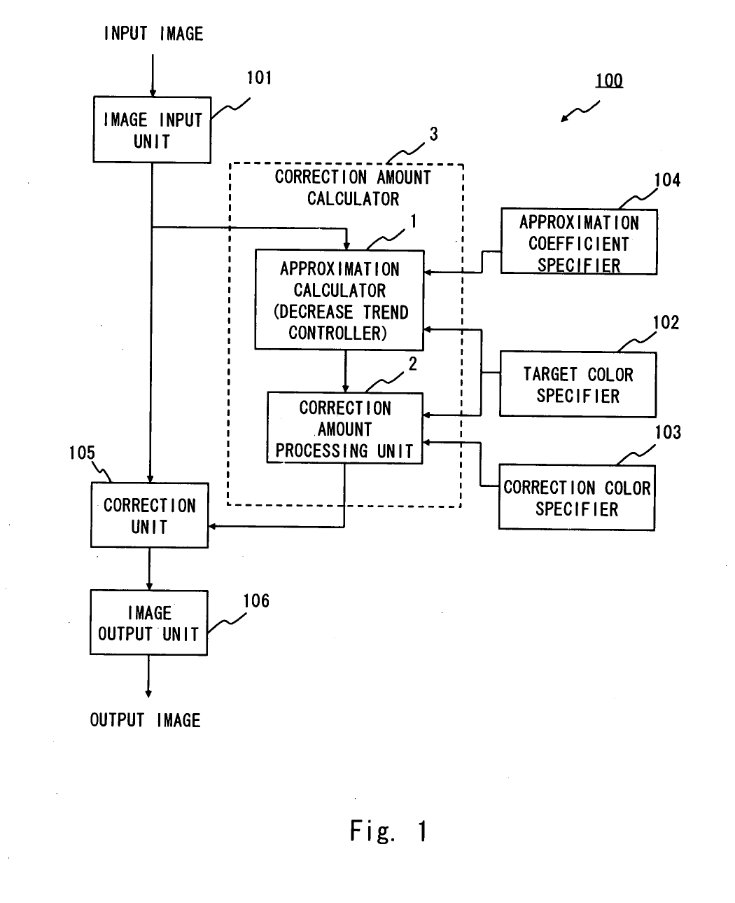

The configuration of the color correction apparatus according to the present embodiment is described hereinafter in detail with reference to the block diagram of FIG. 1. As shown in FIG. 1, a color correction apparatus 100 includes an image input unit 101, a target color specifier 102, a correction color specifier 103, an approximation coefficient specifier 104, a correction amount calculator 3, a correction unit 105, and an image output unit 106. The correction amount calculator 3 further includes an approximation calculator 1 and a correction amount processing unit 2.

The image input unit 101 is for example an input buffer input with an input image constituted of a plurality of pixels. After inputting each pixel of the input image, the image input unit 101 provides the pixels in an order of input to the correction amount calculator 3 of the approximation calculator 1 and the correction unit 105. Each pixel of the input image is color data in the RGB format, for example.

The target color specifier 102 is specified (input) with a target color to be corrected externally and provides the target color to the approximation calculator 1 and the correction amount processing unit 2 of the correction amount calculator 3. The target color is specified in the RGB format, for example.

The correction color specifier 103 is specified (input) with a correction color to be corrected externally and provides the correction color to correction amount processing unit 2 of the correction amount calculator 3. The correction color is specified in the RGB format, for example.

The approximation coefficient specifier 104 is specified (input) with an approximation coefficient to determine a decrease trend of the approximation (approximation characteristic) externally and provides the approximation coefficient to the approximation calculator 1 of the correction amount calculator 3. As the approximation coefficient, a weight specifying the decrease trend (slope) of the approximation, an approximation limit, and a correction range can be considered. In this embodiment, the weight and the approximation limit are specified for the approximation coefficient.

The correction amount calculator 3 calculates an approximation hx that indicates a degree of approximation to the target color for the input pixel, and calculates the correction amount to correct the input pixel according to the approximation hx. The correction amount calculator 3 changes the amount of color correction in a nonlinear manner from inside a particular region toward the boundary. The correction amount calculator 3 reduces the correction amount so that it is reduced to 0 at the boundary of the correction range according to the color distance from the center of the particular region, that is the color distance from the target color in the correction range.

The color calculator 1 calculates the approximation of each pixel constituting the input image according to the decrease trend of the approximation determined by the target color and the approximation coefficient, and then provides the approximation to the correction amount processing unit 2. The approximation hx indicates the degree of approximation of the input pixel to the target color that is to be corrected. The approximation hx is a numeric value from 0 to 1.0 indicating how much the input pixel should be moved in the color space. The color is corrected to be close to the correction color according to the approximation hx. With the approximation hx=1.0, the input pixel are fully corrected to the correction color. With the approximation hx=0.5, the input pixel is corrected to a medium color between the target and correction colors. With the approximation hx=0, the input pixel is not corrected.

In this embodiment, the approximation calculator 1 calculates the approximation so that the decrease trend changes according to the color distance from the target color. Specifically, the approximation calculator 1 is a decrease trend controller for controlling the decrease trend of the correction amount for at least once. To prevent from generating a contouring near the boundary of the correction range, the decrease trend (slope) of the correction amount near the boundary of the correction range is controlled to be more gradual than other regions of the correction amount. Specifically, a decrease rate of the correction amount is reduced as the color distance gets away from the target color.

In this embodiment, the approximation calculator 1 controls the decrease trend of the approximation once by a broken line function having at least two decrease trends according to the target color and the weight and approximation limit, which are the approximation coefficient. The broken line function is a function having a curve that the numeric value indicated by the function turning at least once. The approximation calculator 1 calculates the approximation using two linear functions. The approximation can be calculated using a formula other than the two linear functions as long as the correction amount near the boundary of the correction range is reduced. It may be a function having a plurality of inflection points and extreme values. It may be a plurality of linear functions or more than one multidimensional functions as in a second to fourth embodiments, or a any of different functions may be combined.

The correction amount processing unit 2 calculates the correction amount according to the target and correction colors and the approximation, and then provides the calculated correction amount to the correction unit 105. The correction amount processing unit 2 calculates the correction amount as in “Correction amount=approximation hx*(correction color−target color)”. The correction amount may be calculated by specifying the correction coefficient instead of the correction color as in “Correction amount=approximation hx*correction coefficient”.

The correction unit 105 corrects each pixel of the input image and provides the corrected output pixels to the image output unit 106. The correction unit 105 calculates the output pixels as in “Output pixel=input pixel+correction amount”. The image output unit 106 is an output buffer, for example, that is sequentially input with output pixels being corrected, and outputs the output pixels to outside as an output image.

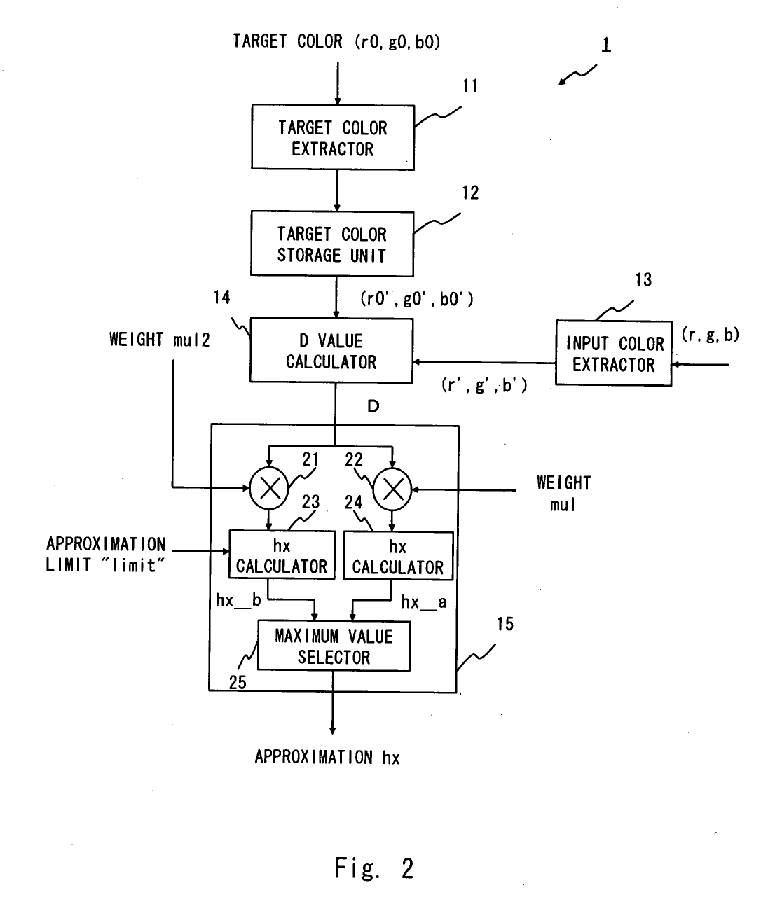

The configuration of the approximation calculator of a color correction apparatus according to the present embodiment is described hereinafter in detail with reference to the block diagram of FIG. 2. The approximation calculator of this embodiment calculates the approximation hx in the RGB format. As shown in FIG. 2, the approximation calculator 1 includes a target color component extractor 11, a target color component storage unit 12, an input color component extractor 13, a D value calculator 14, and an hx output unit 15. Further, the hx output unit 15 includes multipliers 21 and 22, hx calculators 23 and 24, and a maximum value selector 25.

The target color component extractor 11 extracts color components (r0′, g0′, b0′) of the target color (r0, g0, b0) specified by the target color specifier 102. The target color component storage unit 21 stores the color components (r′, g′, b′) of the target color extracted by the target color component extractor 11.

The input color component extractor 13 extracts color components (r′, g′, b′) of the input pixel (r, g, b) input from the image input unit 101. The D value calculator 14 calculates a D value that indicates the color distance between the color components (r0′, g0′, b0′) of the target color stored to the target color component storage unit 12 and the color components (r′, g′, b′) of the input pixel extracted by the input color component extractor 13.

The hx output unit 15 calculates and outputs the approximation hx according to the D value calculated by the D value calculator 14, weights mul and mul2, and approximation limit “limit” specified by the approximation coefficient specifier 104.

The multiplier 22 multiplies the D value by the weight mul. The hx calculator 24 calculates the approximation hx by the linear function using the multiplication result of the multiplier 22. The multiplier 22 and the hx calculator 24 calculate a first approximation obtained from a first linear function. The multiplier 22 and the hx calculator 24 form a first decrease trend calculator for controlling the approximation to be in a first decrease trend.

The multiplier 21 multiplies the D value by the weight mul2. The hx calculator 23 calculates the approximation hx by the linear function using the multiplication result of the multiplier 21 and the approximation limit “limit”. The multiplier 21 and the hx calculator 23 calculate a second approximation obtained from a second linear function. The multiplier 21 and the hx calculator 23 form a second decrease trend calculator for controlling the approximation to be in a second decrease trend. The second decrease trend is a trend that suppresses the first decrease trend, specifically a slope of the second decrease trend is more gradual than that of the first decrease trend.

The maximum value selector 25 selects the maximum value between the calculation results by the hx calculators 23 and 24, and then outputs the selected value as the approximation hx. Specifically the maximum value selector 25 selects either a first approximation obtained by the multiplier 22 and the hx calculator 24 or a second approximation obtained by the multiplier 21 and the hx calculator 23.

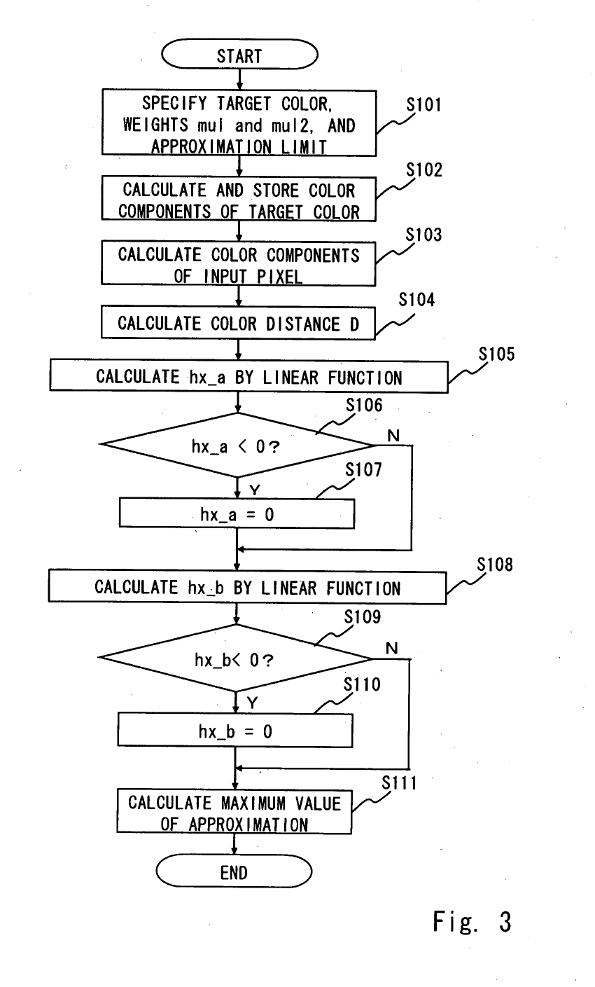

An approximation calculation method by the approximation calculator 1 of the color correction apparatus according to the present embodiment is described hereinafter in detail with reference to the flowchart of FIG. 3. Firstly the target color (r0, g0, b0), the weights mul and mul2, and the approximation limit “limit” are specified to the approximation calculator 1 (S101).

Then the target color component extractor 11 calculates the color components (r0′, g0′, b0′) of the specified target color removed with white color component and store it to the target color component storage unit 12 (S102). The target color component extractor 11 subtracts the minimum value of the RGB value of the target color from the input pixel so as to remove the white color component and extract only the color components as in “(r0′, g0′, b0′)=(r0, g0, b0)−min (r0′, g0′, b0′)”. The min(r0′, g0′, b0′) is a function for selecting the minimum value from r0, g0, and b0.

After that the input color component extractor 13 calculates the color components (r′, g′, b′) of the input pixel (r, g, b) being input (S103). The input color component extractor 13 subtracts the minimum value of the RGB value of the input pixel from the input pixel so as to remove the white color component and extract only the color components as in “(r′, g′, b′)=(r, g, b)−min(r, g, b)”.

Then the D value calculator 14 calculates the color distance D from the color components (r0, g0, b0) of the target color stored in the target color component storage unit 12 and the color components (r′, g′, b′) of the input pixel calculated by the input color component extractor 13 (S104).

The D value calculator 14 calculates a difference (dr, dg, db) of the color components as in “(dr, dg, db)=(r0′−r′, g0′−g′, b0′−b′)”. Then the D value calculator 14 calculates the D value by adding a positive absolute value of a maximum dmax1 in (dr, dg, db) and a negative absolute value of a maximum dmax2 in (dr, dg, db) as in “D=dmax1+dmax2”.

Then the hx output unit 15 calculates and outputs the approximation hx after S105. Firstly the multiplier 22 and the hx calculator 24 calculate an approximation hx_a by a linear function including the D value and the weight mul (S105). Specifically, the approximation hx_a is calculated by the formula 2 below.

hx_{—}a=1.0−mul*D (Formula 2)

After that the hx calculator 24 evaluates whether the approximation hx_a is smaller than 0 (S106). If the approximation hx_a is smaller than 0, the approximation hx_a=0 (S107).

Then the multiplier 21 and the calculator 23 calculate an approximation hx_b by a linear function including the D value, the weight mul2, and the approximation limit “limit” (S108). Specifically, the approximation hx_b is calculated by the formula 3 below. In this example the limit is: 0<=limit<=1.0

hx_{—}b=limit−mul2*D (Formula 3)

After that, the hx calculator 23 evaluates whether the approximation hx_b is smaller than 0 (S109). If the approximation hx_b is smaller than 0, the approximation hx_b=0 (S110).

Then the maximum value selector 25 selects the maximum value between the approximations hx_a and hx_b, and outputs the maximum value as the approximation hx (S111). Therefore in this embodiment, one having a larger value between the formulas 2 and 3 is the approximation hx.

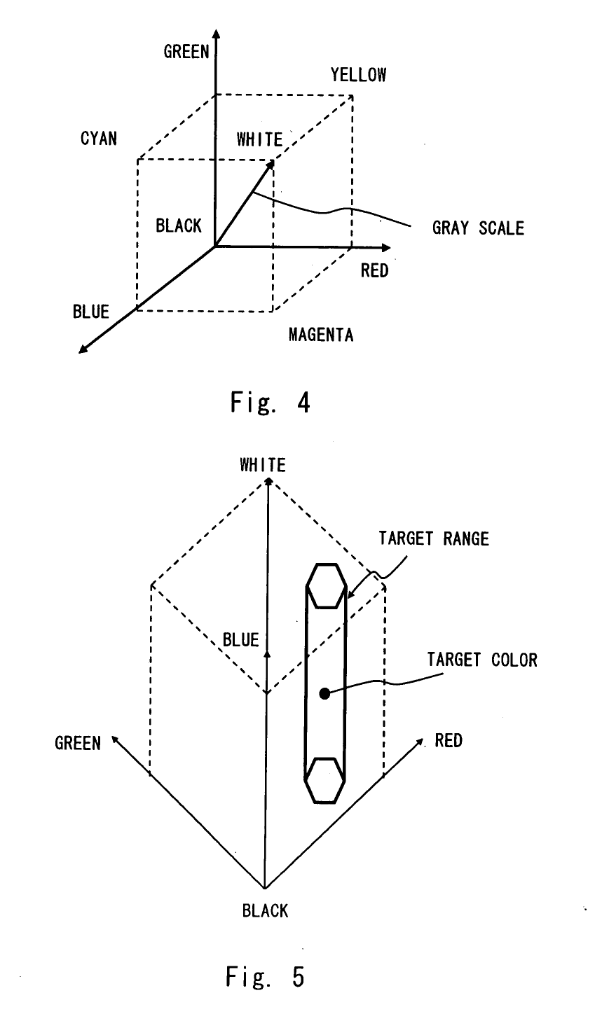

The RGB color space used in the calculation of the approximation hx according to the present embodiment is described hereinafter in detail. FIG. 4 is a general RGB color space. The RGB color space is represented by a three-dimensional coordinate with red, blue, and green axes orthogonal to each other. With blue being 0, and green and red being 1, the color is yellow. With red being 0, and the green and blue being 1, the color is cyan. With green being 0, and red and blue being 1, the color is magenta. With red, blue, and green being all 0, the color is black. With red, blue, and green being all 1, the color is white. The axis connecting the black and white is gray scale. However a range the red, blue, and green can take shall be 0<=red, and blue and green <=1.

FIG. 5 is an image of the correction range in which the approximation hx is calculated by the method of FIG. 3. Specifically in FIG. 3, the D value is calculated using the target color and only the color components of the input pixel removed with the white color component. Thus in FIG. 5, the pixels having the same color components with the target color at the center are the correction range. In this case, the correction amount becomes the same as long as the color components are the same, thus not depending on the white color component.

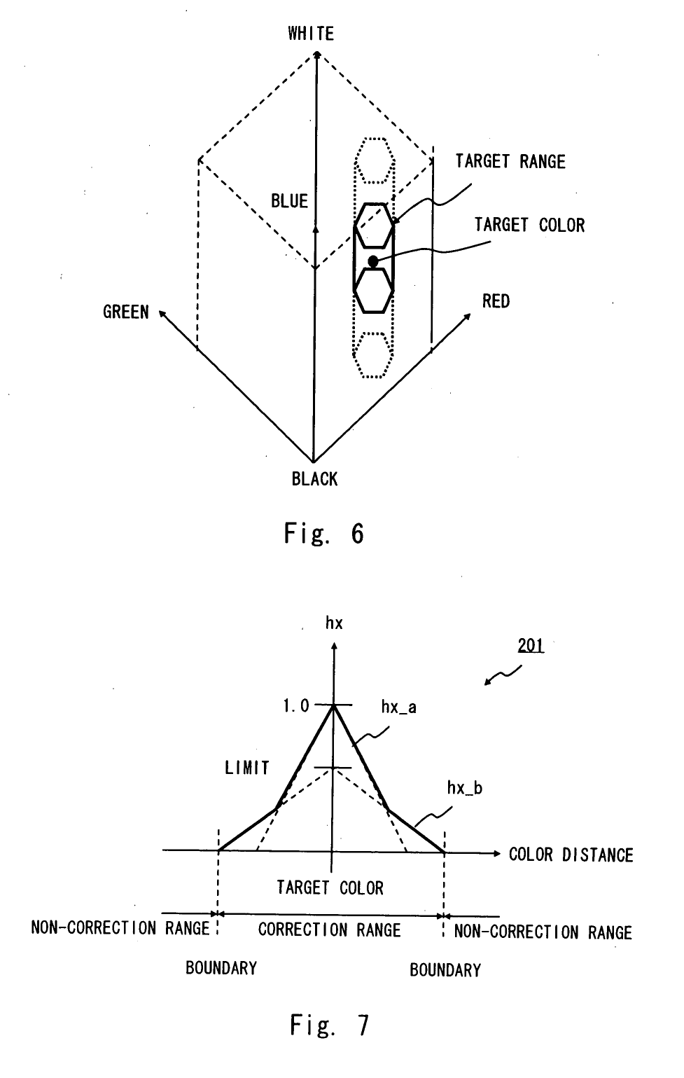

The approximation hx can be calculated without removing the white color component other than the method of FIG. 3. In S104, the D value may be calculated by the difference between the target color including the white color component and input pixel, where the difference is “(dr, dg, db)=(r0−r,g0−g,b0−b)”, so as to calculate the approximation hx. FIG. 6 is an image of the correction range in which the approximation hx is calculated without removing the white color component. Specifically, as the D value is calculated including the white color component, the correction range is the range with the white color component direction being limited and the target color at the center. In this case, any gray scale range may be corrected. In the following embodiments, to calculate the approximation hx in the RGB format, a range with no limitation in the white color component direction may be the correction rang, as in FIG. 5, or a range with the limitation in the white color component direction may be the correction range as in FIG. 6.

FIG. 7 is an image of the approximation hx (approximation characteristic) to the color distance from the target color calculated by the approximation calculator 1. An approximation characteristic 201 is calculated from the maximum value of the formulas 2 and 3. Specifically, the approximation characteristic 201 is a characteristic extending with its center at the approximation hx=1.0 of the target color, the approximation decreasing to 0 as the color distance to the target color increases. The correction range is a range surrounded by the boundary contacting the color distance (horizontal) axis of hx=0, and a range distant to the correction range is non-correction range.

In this embodiment, if the value of the formula 2 is specified to be larger in the region near the target color, hx_a is the approximation hx, in which the decrease trend of the approximation hx is determined by “−mul*D”. Further, if the value of the formula 3 is specified to be larger in the region near the correction range, hx_b is the approximation hx, in which the decrease trend of the approximation hx is determined by “−mul2*D”.

The approximation characteristic 201 specifies the weight mul2 and the approximation limit “limit” so that the formula 3 is selected near the boundary of the correction range. In addition to that, by specifying the value of the weight mul2 to be smaller so as to have small correction amount, a sudden color change near the boundary of the correction range can be suppressed.

As described herein, in this embodiment the function to reduce the correction amount near the boundary of the correction range is selected in the calculation of the approximation. Accordingly the change of the color near the boundary of the correction range can be suppressed as well as preventing to generate the contouring.

### Second Embodiment

A color correction apparatus according to a second embodiment of the present invention is described hereinafter in detail. In this embodiment, as an example of reducing the correction amount near the boundary of the correction range, a quadratic function is used to calculate the approximation in the RGB format.

An entire configuration of the color correction apparatus of this embodiment is identical to the one shown in FIG. 1 of the first embodiment. In this example, the approximation coefficient specified by the approximation coefficient specifier 104 is the correction range. The approximation calculator (decrease trend controller) 1 continuously suppresses the decrease trend of the approximation. The approximation calculator 1 calculates the approximation according to the target color and the correction range, which is the approximation coefficient, so that the decrease trend of the approximation is suppressed by a multidimensional function. In this embodiment, the approximation is calculated using the quadratic function as the multidimensional function.

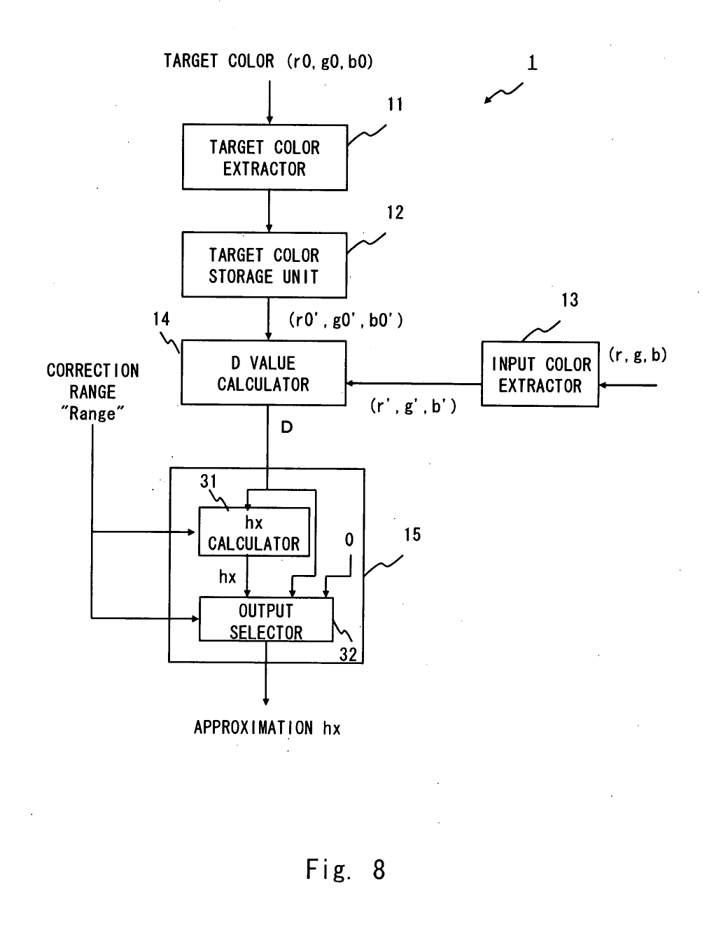

FIG. 8 is a block diagram showing a configuration of the approximation calculator of the color correction apparatus according to the present embodiment. In FIG. 8, components denoted by reference numerals to FIG. 2 are identical components. In the approximation calculator 1 of this embodiment, the configuration of the hx output unit 15 is different as compared to the configuration of FIG. 2. The hx output unit 15 includes an hx calculator 31 and an output selector 32.

The hx output unit 15 calculates and outputs the approximation hx according to the D value calculated by the D value calculator 14 and a correction range “Range” specified by the approximation coefficient specifier 104. The hx calculator 31 calculates the approximation hx by the quadratic function using the D value and the correction range “Range”. The output selector 32 selects either the approximation calculated by the hx calculator 31 or 0 and outputs it as the approximation hx.

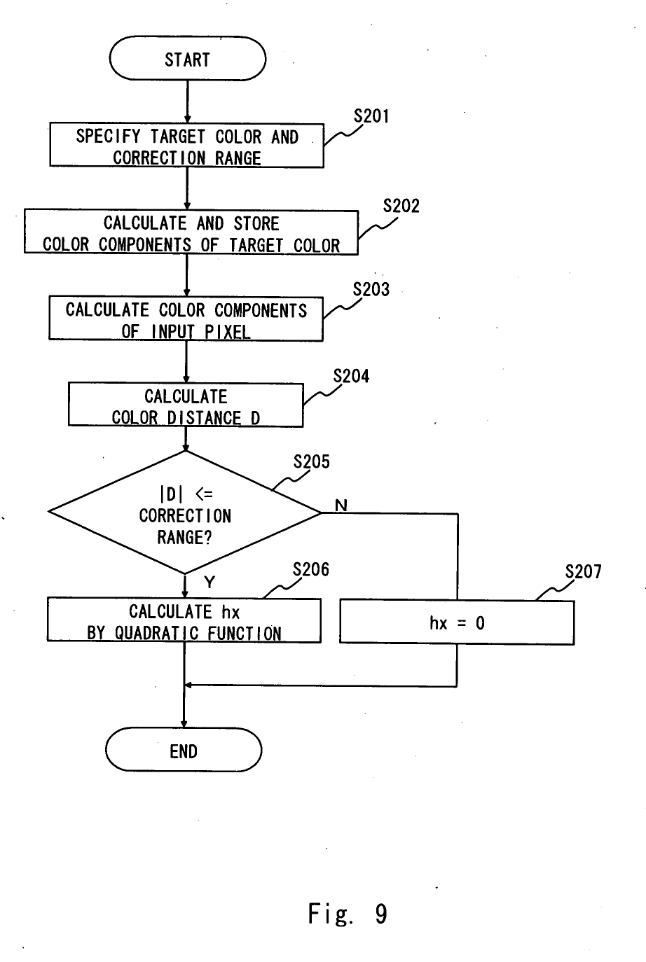

FIG. 9 is a flowchart showing an approximation calculation method by the color correction apparatus of this embodiment. Firstly the target color and the correction range “Range” are specified to the approximation calculator 1 (S201). Then the target color and the correction range “Range” are specified to the approximation calculator 1 (S201). After that the color components of the target color is calculated and stored as in FIG. 3 (S202). Then the color components of the input pixel are calculated (S203). After that, the color distance D is calculated from the color components of the target color and the color components of the input pixel (S204).

Then the hx output unit 15 calculates and outputs the approximation hx after S205. Firstly the output selector 32 evaluates whether the absolute value of the D value is less than the correction range “Range” (S205). If the absolute value of the D value is less than the correction range “Range”, the hx calculator 31 calculates the approximation hx by the quadratic function including the D value and the correction range “Range” (S206). Specifically the approximation hx can be calculated by the formula 4 below.

hx=((Range−|D|)²)/(Range²) (Formula 4)

If the absolute value of the D value is larger than the correction range “Range”, the output selector 32 determines that the approximation hx=0 (S207). Accordingly in this embodiment, the value of the formula 4 is the approximation hx in the correction range “Range”, and the approximation hx is 0 outside the range of the correction range “Range”.

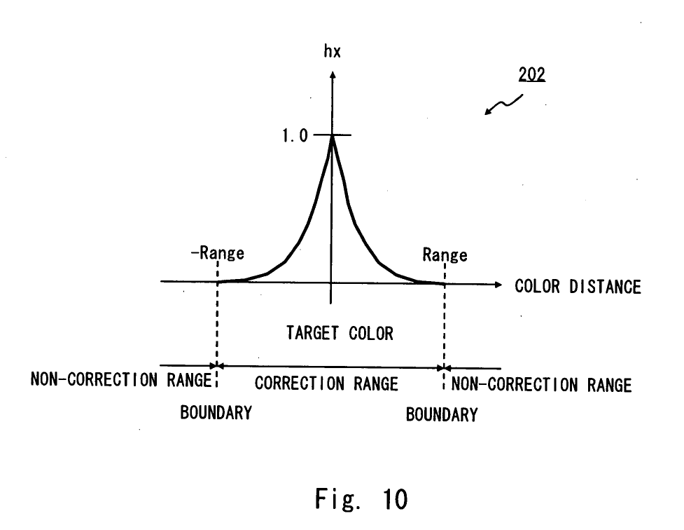

FIG. 10 is an image of the approximation hx (approximation characteristic) to the color distance from the target color calculated by the approximation calculator 1. An approximation characteristic 202 is calculated by the formula 4. Specifically the approximation characteristic 202 is a symmetric characteristic with its center at the approximation hx=1.0 of the target color, the approximation decreasing to 0 as the color distance to the target color increases. The correction range is a range surrounded by the boundary contacting the color distance (horizontal) axis of hx=0, in this example from −Range to Range, and a range distant to the correction range is non-correction range.

In this embodiment, the decrease trend continuously changes depending on the color distance by the quadratic function of the formula 4. Specifically, the decrease trend of the approximation characteristic 202 is continuously suppressed by the quadratic function of the formula 2 according to the color distance from the target color. The slope of the approximation characteristic 202 gently becomes gradual as it gets away from the target color, and becomes close to the direction of the color distance axis near the boundary of the correction range.

As described in the foregoing, the correction amount near the boundary of the correction range is reduced by calculating the approximation using the quadratic functions. Accordingly as with the first embodiment, it is possible to suppress the color change near the boundary of the correction range, as with the first embodiment, and also to prevent from generating contouring.

In this embodiment, by using the quadrant function, the slope gently changes according to the color distance, thereby not generating a broken angle from the target color to the correction range. Thus it is possible to prevent from generating contouring from the target color to the correction range.

### Third Embodiment

A color correction apparatus according to a third embodiment of the present invention is described hereinafter in detail. In this embodiment, as an example of reducing the correction amount near the boundary of the correction range, a cubic function is used to calculate the approximation in the RGB format.

An entire configuration of the color correction apparatus of this embodiment is identical to the one shown in FIG. 1 of the first embodiment. The configuration of the approximation calculator 1 is identical to the second embodiment in FIG. 8. In this embodiment the approximation coefficient specified by the approximation coefficient specifier 104 is the correction range as with the second embodiment.

The approximation calculator 1 calculates the correction amount using the multidimensional function according to the target color and the correction range, which is the approximation coefficient. In this embodiment, the correction amount is calculated using the cubic function as the multidimensional function. In the approximation calculator 1, the hx calculator 31 of the hx output unit 15 calculates the approximation hx by the cubic function using the D value and the correction range “Range”.

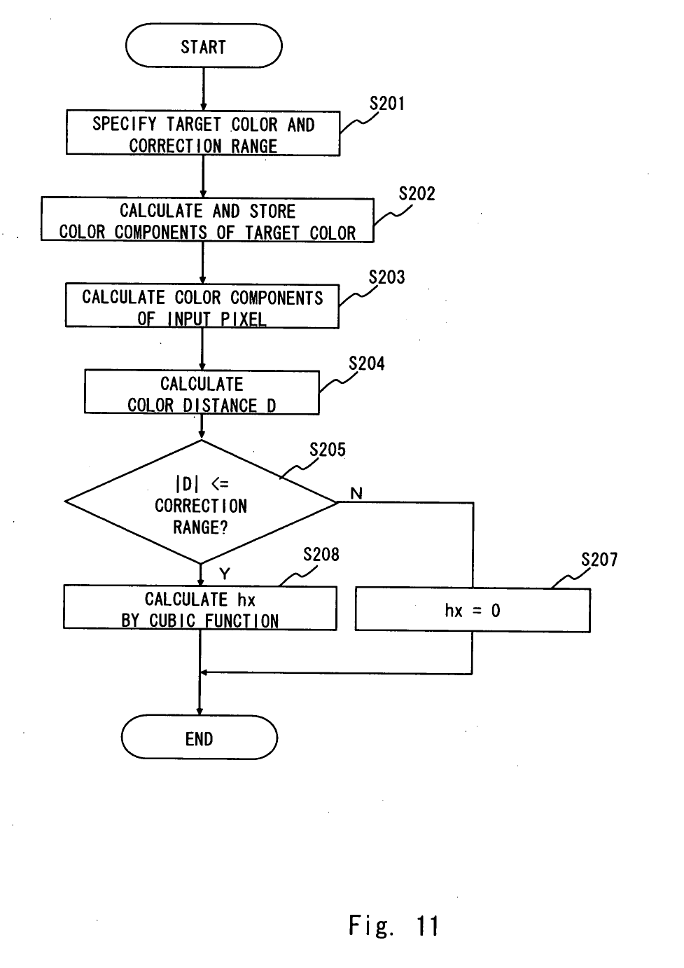

FIG. 11 is a flowchart showing an approximation calculation method by the color correction apparatus of this embodiment. In FIG. 11, components denoted by reference numerals to those in FIG. 9 are identical processes to those in FIG. 9. Firstly as with the FIG. 9, from S201 to S204, the target color and the correction range “Range” are specified, the color components of the target color are calculated and stored, the color components of the input pixel are calculated, and the color distance D is calculated.

Then the hx output unit 15 calculates and outputs the approximation hx after S205. Firstly as with FIG. 9, it is evaluated whether the absolute value of the D value is less than the correction range “Range” (S205). Then the absolute value of the D value is larger than the correction range “Range”, the approximation hx=0 (S207).

If the absolute value of the D value is less than the correction range “Range”, the hx calculator 31 calculates the approximation hx by the cubic function including the D value and the correction range “Range” (S208). Specifically the approximation hx can be calculated by the formula 5 below.

hx=(2*(Range−|D|)³)/(Range³)−(3*(Range−|D|)²)/(Range²)+1 (Formula 5)

Accordingly in this embodiment, the value of the formula 5 is the approximation hx in the correction range “Range”, and the approximation hx is 0 outside the range of the correction range “Range”.

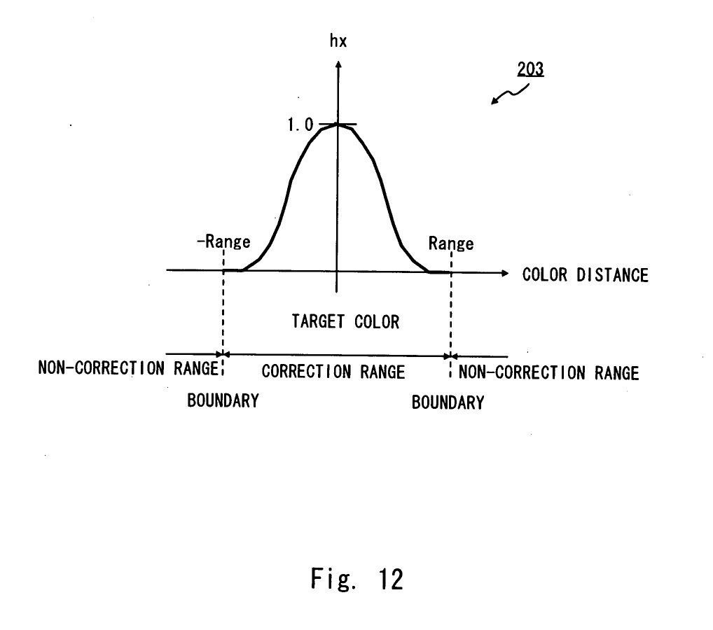

FIG. 12 is an image of the approximation hx (approximation characteristic) to the color distance from the target color calculated by the approximation calculator 1. An approximation characteristic 203 is calculated by the formula 5. Specifically the approximation characteristic 203 is a symmetric characteristic with its center at the approximation hx=1.0 of the target color, the approximation decreasing to 0 as the color distance to the target color increases. The correction range is a range surrounded by the boundary contacting the color distance (horizontal) axis of hx=0, in this example from −Range to Range, and a range distant to the correction range is non-correction range.

In this embodiment, the decrease trend continuously changes according to the color distance by the cubic function of the formula 5. Specifically for the approximation characteristic 203, the decrease trend is continuously suppressed according to the color distance from midpoint to the correction range “Range” that is distant from the target color, by the cubic function of the formula 5. The slope of the approximation characteristic 203 gently becomes gradual as it gets away from midpoint to the correction range “Range” that is distant from the target color, and becomes close to the direction of the color distance axis near the boundary of the correction range.

As described in the foregoing, the correction amount near the boundary of the correction range is reduced by calculating the approximation using the cubic functions. Accordingly as with the first embodiment, it is possible to suppress the color change near the boundary of the correction range and also to prevent from generating contouring.

Furthermore in this embodiment, by using the cubic function, the slope gently changes according to the color distance as with the second embodiment. Thus it is possible to prevent from generating contouring in the correction range from the target color to the correction range. Further in this embodiment, by using the cubic function, the top of the target color becomes a gradual curve, thereby suppressing the color change near the target color.

### Fourth Embodiment

A color correction apparatus according to a fourth embodiment of the present invention is described hereinafter in detail. In this embodiment, as an example of reducing the correction amount near the boundary of the correction range, two quadratic functions are used to calculate the approximation in the RGB format.

An entire configuration of the color correction apparatus of this embodiment is identical to the one shown in FIG. 1 of the first embodiment. In this example, the approximation coefficient specified by the approximation coefficient specifier 104 is two correction ranges (Range and Pos). The approximation calculator 1 calculates the correction amount by the two multidimensional functions according to the target color and two correction ranges, which are the approximation coefficient. Specifically, the approximation calculator (decrease trend controller) 1 selects either a first approximation obtained by a first multidimensional function or a second approximation obtained by a second multidimensional function. In this embodiment, a quadratic function is used to calculate the correction amount as the multidimensional function.

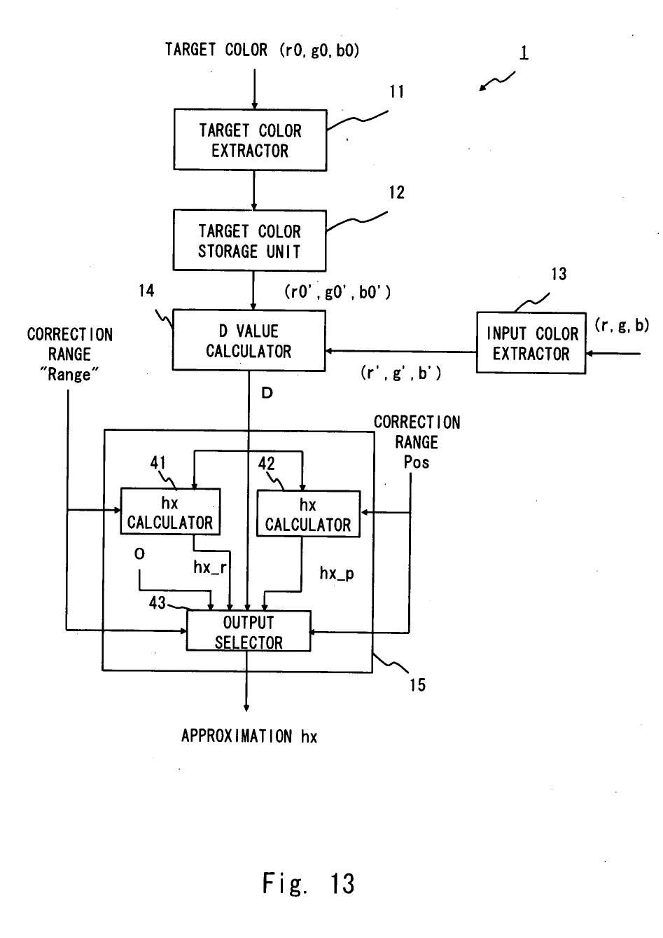

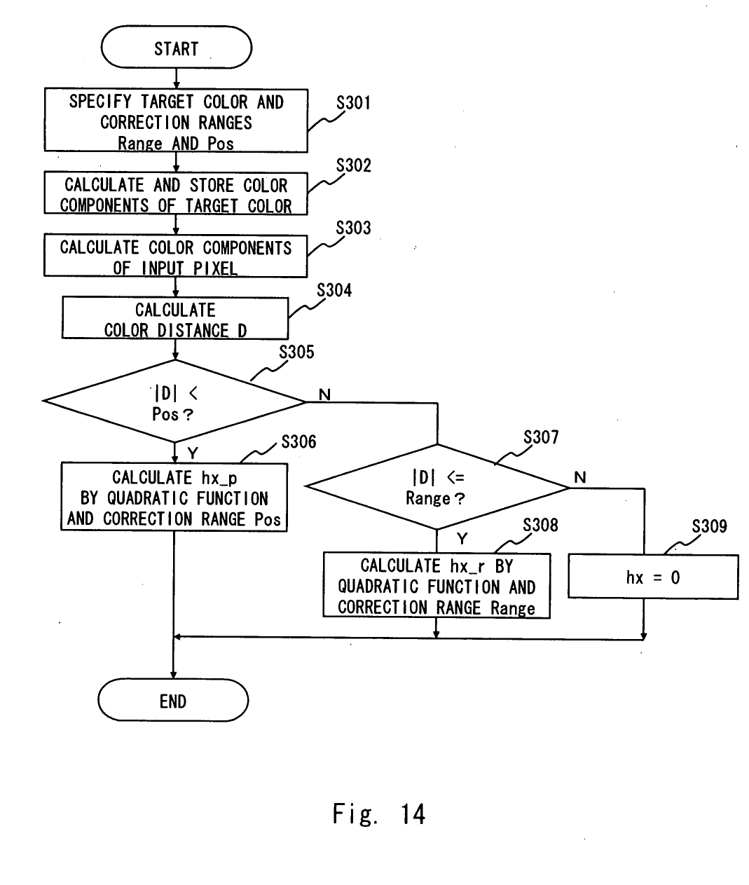

FIG. 13 is a block diagram showing a configuration of the approximation calculator of the color correction apparatus according to the present embodiment. In FIG. 13, components denoted by reference numerals to FIG. 2 are identical components. In the approximation calculator 1 of this embodiment, the configuration of the hx output unit 15 is different as compared to the configuration of FIG. 2.

The hx output unit 15 includes hx calculators 41 and 42, and an output selector 43. The hx output unit 15 calculates and outputs the approximation hx according to the D value calculated by the D value calculator 14 and the correction ranges Range and Pos specified by the approximation coefficient specifier 104.

The hx calculator 41 calculates an approximation hx_r by the quadratic function using the D value and the correction range “Range”. Specifically, the hx calculator 41 calculates the first approximation using the first multidimensional function in the correction range “Range” (a first correction range). The hx calculator 42 calculates an approximation hx_p by the quadratic function using the D value and the correction range Pos. Specifically, the hx calculator 42 calculates the second approximation by the second multidimensional function, different from the first multidimensional function, in the correction range Pos (a second correction range). The output selector 43 selects either the hx_r calculated by the hx calculator 41, the approximation hx_p calculated by the hx calculator 43, or 0 and outputs it as the approximation hx.

FIG. 14 is a flowchart showing an approximation calculation method by the color correction apparatus of this embodiment. Firstly the target color and the correction ranges Range and Pos are specified to the approximation calculator 1 (S301). Then the color components of the target color are calculated and stored as with FIG. 3 (S301). After that the color components of the input pixel are calculated (S303). Then the color distance D is calculated from the color components of the target color and the input pixel (S304).

After that the hx output unit 15 calculates and outputs the approximation hx after S305. Firstly the output selector 43 evaluates whether the absolute value of the D value is less than the correction range Pos (S305). If the absolute value of the D value is less than the correction range Pos, the hx calculator 42 calculates the approximation hx_p by the quadratic function including the D value and the correction range Pos (S306). Specifically the approximation hx_p can be calculated by the formula 6 below.

hx_{—}p=−(|D|²)/(Range*Pos)+1 (Formula 6)

Further, if the absolute value of the D value is larger than the correction range Pos, the output selector 43 evaluates whether the absolute value of the D value is less or equal to the correction range “Range” (S307). If the absolute value of the D value is less or equal to the correction range “Range”, the hx calculator 41 calculates the approximation hx_r by the quadratic function including the D value and the correction range “Range” (S308). Specifically the approximation hx_r can be calculated by the formula 7 below.

hx_{—}r=((Range−|D|)²)/(Range*(Range−Pos)) (Formula 7)

If the absolute value of the D value is larger than the correction range “Range” in S307, the output selector 43 determines that the approximation hx=0 (S309). Accordingly in this embodiment, the value of the formula 6 is the approximation hx in the range of the correction range Pos, the value of the formula 7 is the approximation hx in the ranges from the correction range Pos to the correction range “Range”, and the approximation hx is 0 outside the range of the correction range “Range”.

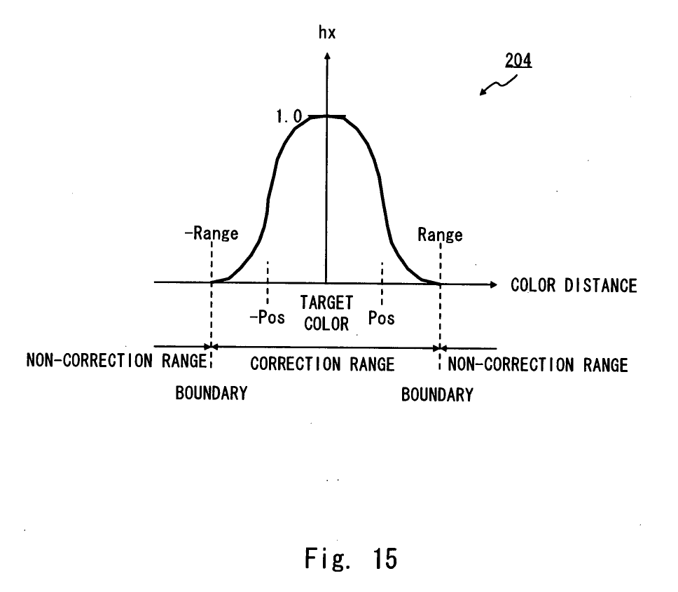

FIG. 15 is an image of the approximation hx (approximation characteristic) to the color distance from the target color calculated by the approximation calculator 1. An approximation characteristic 204 is calculated by the formulas 6 and 7. Specifically the approximation characteristic 204 is a symmetric characteristic with its center at the approximation hx=1.0 of the target color. The approximation characteristic 204 decreases to 0 as it gets away from the target color. The correction range is a range surrounded by the boundary contacting the color distance (horizontal) axis of hx=0, in this example from −Range to Range, and a range distant to the correction range is non-correction range.

In this embodiment, the decrease trend continuously changes depending on the color distance by the quadratic functions of the formulas 6 and 7. Specifically from the target color to the correction range Pos, the approximation characteristic 204 gently decreases as it gets away from the target color by the cubic function of the formula 6, and greatly reduces near the boundary of the correction range Pos. From the correction ranges Pos to Range, the decrease trend is continuously suppressed by the cubic function of the formula 7 as it gets away form the target color. The slope of the approximation characteristic 204 gently becomes more gradual as it gets away from the target color from the correction ranges Pos to Range, and becomes close to the direction of the color distance axis near the boundary of the correction range.

As described in the foregoing, the correction amount near the boundary of the correction range is reduced by calculating the approximation using two quadratic functions. Accordingly as with the first embodiment, it is possible to suppress the color change near the boundary of the correction range and also to prevent from generating contouring.

In this embodiment, by using the two quadratic functions, the slope gently changes according to the color distance as with the second and the third embodiment. Thus it is possible to prevent from generating contouring from the target color to the correction range. By using two quadratic functions, the color change near the target color can be suppressed, as with the third embodiment. By changing the point to switch the function Pos, the amount of the color change near the boundary of the correction range can either be reduced or increased.

### Fifth Embodiment

A color correction apparatus according to a fifth embodiment of the present invention is described hereinafter in detail. In this embodiment, as an example of reducing the correction amount near the boundary of the correction range, the function of the fourth embodiment is used to calculate the approximation in the HSV format.

An entire configuration of the color correction apparatus of this embodiment is identical to the one shown in FIG. 1 of the first embodiment. The target color is specified in the HSV format to the target color specifier 102. Weights of hue H, saturation S, and value V are specified as the approximation coefficient in the HSV format.

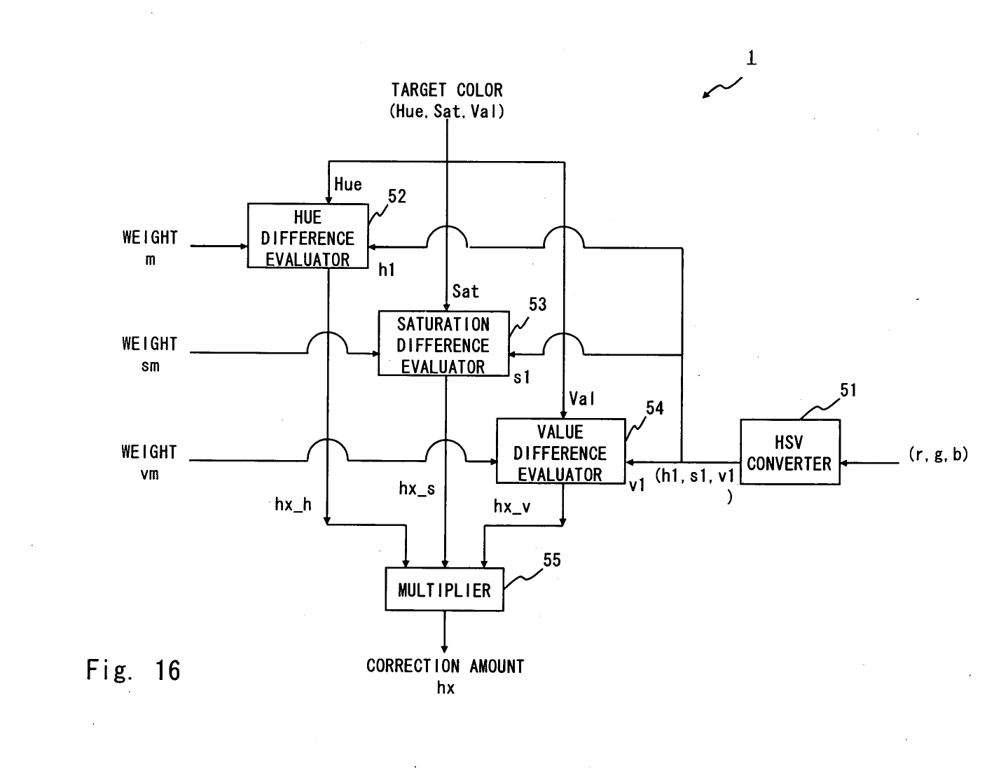

FIG. 16 is a block diagram showing a configuration of the approximation calculator of the color correction apparatus according to the present embodiment. The color correction apparatus of this embodiment calculates the approximation in the HSV format. As shown in FIG. 16, the approximation calculator 1 includes an HSV converter 51, a hue difference evaluator 52, a value difference evaluator 53, a value difference evaluator 54, and a multiplier 55.

The HSV converter 51 converts the input pixel (r, g, b) of the RGB format input from the image input unit 101 into input pixel (h1, s1, v1) of the HSV format. The hue component h1 of the input pixel is given to the hue difference evaluator 52, the saturation component s1 of the input pixel is given to the saturation difference evaluator 53, and the value component v1 of the input pixel is given to the value difference evaluator 54. A range of the HSV value in this document is 0<=S, V<=1.0, and 0<=H<360 (see Japanese Unexamined Patent Application Publication No. 10-198795 for details).

The hue difference evaluator 52 calculates an approximation hx_h of the target color specified by the target color specifier 102 according a hue component Hue of the target color specified by the target color specifier 102 and a weight m of the hue component, which is the approximation coefficient. The saturation difference evaluator 53 calculates an approximation hx_s of the saturation component s1 of the input pixel according to a saturation component Sat of the target color specified by the target color specifier 102 and a weight sm of the saturation component, which is the approximation coefficient. The value difference evaluator 54 calculates an approximation hx_v of the value component v1 of the input pixel according to the value component Val of the target color specified by the target color specifier 102 and a weight vm of the value components, which is the approximation coefficient.

The multiplier 55 multiplies the approximation hx_h of the hue component, the approximation hx_s of the saturation components, and the approximation hx_v of the value component, and then outputs the multiplication result as the approximation hx.

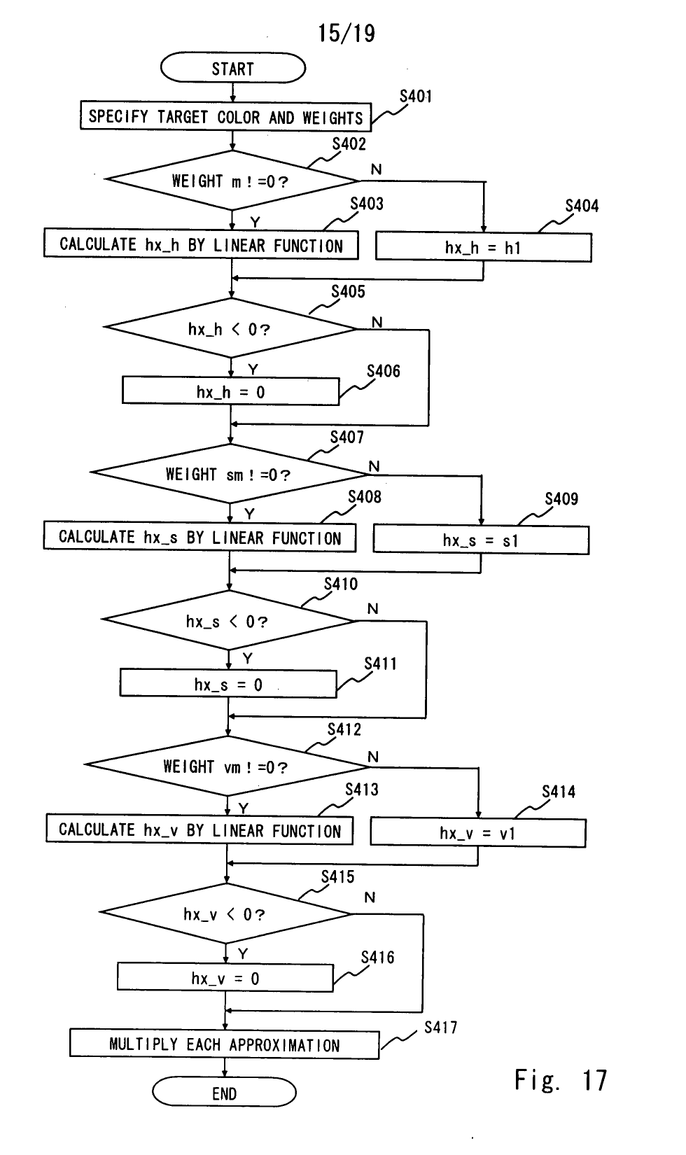

FIG. 17 is a flowchart showing an approximation calculation method by the color correction apparatus of this embodiment. Firstly, the target color (Hue, Sat, Val) and weights m, sm, and vm are specified to the approximation calculator 1 (S401).

Then from S402 to 406, the hue difference evaluator 52 calculates the approximation hx_h of the hue component. Specifically, the hue difference evaluator 52 evaluates whether the weight m is 0 or not (S402). If the weight m is not 0, the approximation hx_h is calculated by a linear function including the weight m (S403). Specifically the approximation hx_h is calculated by the formula 8 below.

hx_{—}h=(m−|h1−Hue|)/m (Formula 8)

If the weight m is 0 in S402, the approximation hx_h=h1. Then the hue difference evaluator 52 evaluates whether the approximation hx_h is smaller than 0 (S405). If the approximation hx_h is smaller than 0, the approximation hx_h=0 (S406).

Then from S407 to S411, the saturation difference evaluator 53 calculates the approximation hx_s of the saturation component by the saturation difference evaluator 53. Specifically, the saturation difference evaluator 53 evaluates whether the weight sm is 0 (S407). If the weight sm is not 0, the approximation hx_s is calculated by a linear function including the weight sm (S408). Specifically the approximation hx_h is calculated by the formula 9 below.

hx_{—}s=(sm−|s1−Sat|)/sm (Formula 9)

If the weight sm is 0 in S407, the approximation hx_s=s1 (S409). Then the saturation difference evaluator 53 evaluates whether the approximation hx_s is smaller than 0 (S410). If the approximation hx_s is smaller than 0, the approximation hx_s=0 (S411).

Then from S412 to S416, the value difference evaluator 54 calculates the approximation hx_v of the value component by the value difference evaluator 54. Specifically, the value difference evaluator 54 evaluates whether the weight vm is 0 (S412). If the weight vm is not 0, the approximation hx_v is calculated by a linear function including the weight vm (S413). Specifically the approximation hx_v is calculated by the formula 10 below.

hx_{—}v=(vm−|v1−Val|)/vm (Formula 10)

If the weight vm is 0 in S412, the approximation hx_v=v1 (S414). Then the value difference evaluator 54 evaluates whether the approximation hx_v is smaller than 0 (S415). If the approximation hx_v is smaller than 0, the approximation hx_v=0 (S416).

Then the multiplier 55 multiplies the approximations hx_h, hx_s, and hx_v as in the formula 11

hx=hx_{—}h*hx_{—}s*hx_{—}v (Formula 11)

A HSV color space used to calculate the approximation hx according to the present embodiment is described hereinafter in detail. FIG. 18 is an image of a general HSV color space. The HSV color space is represented by a six-sided pyramid. A central axis of the six-sided pyramid is the value V, the axis extending from the central axis to periphery is the saturation S, and an angle in a direction rotating around the central axis is the hue H. Changing the hue H where the value V and the saturation S at maximum, it changes to red, yellow, green, cyan, blue, and magenta by every 60 degrees. The saturation S is becomes the highest and most vivid color around the periphery and becomes diluted near the central axis. The value V is the darkest near the six-sided pyramid's top and the brightest near the base of the six-sided pyramid. The central axis of the six-sided pyramid corresponds to gray scale, with the six-sided pyramid's top of the bottom part is black and the base of the six-sided pyramid of the upper part is white.

To calculate the approximation hx by the method of FIG. 17, any portion of the HSV color space can be the correction range by the approximation coefficient of HSV. For example if the approximation hx is calculated with the weight m>0, weight sm>0, and weight vm>0, the correction range is the range determined by the weight m of the hue H, the range determined by the weight sm of the saturation S, and the weight vm of value V, as with Japanese Unexamined Patent Application Publication No. 10-198795.

The formulas used for the approximation hx in the first to fourth embodiments can be applied to each of the hue difference evaluator 52, the saturation difference evaluator 53, and the value difference evaluator 54. Taking an example with the hue difference evaluator 52, the formula 8 becomes the following formula 9.

hx_{—}h=(m−|h1−Hue|)/m=1−1/m*|h1−Hue| (Formula 9)

### Supposing that 1/m=mul and |h1−Hue|=D, the formula 9 becomes “hx_{—}=1−mul*D”, which is the same as the formula 2 or the like.

As described in the foregoing, to calculate the approximation hx in the HSV format, by calculating the approximation hx using the plurality of linear functions and any multidimensional function for the hue, saturation, and value components as with the RGB format, it is possible to reduce the correction amount near the boundary of the correction range and also to prevent from generating contouring.

### Other Embodiment

The color correction apparatus 100 may be configured only by hardware in a display device such as a television, or a specific means that software and hardware is cooperating in a computer such as a personal or server computer.

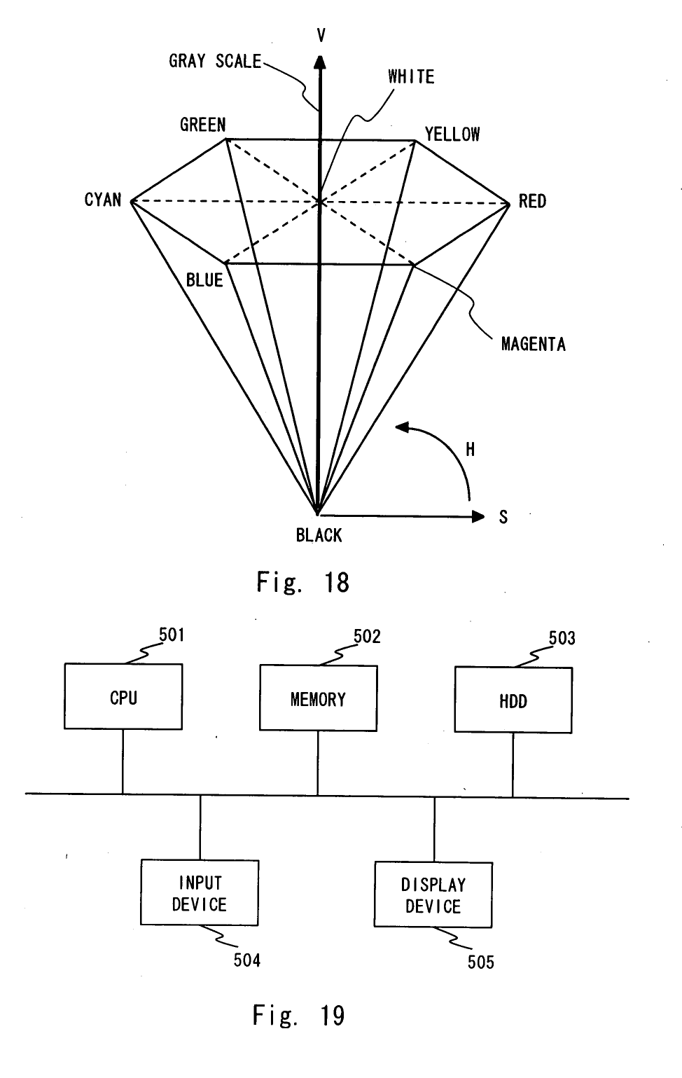

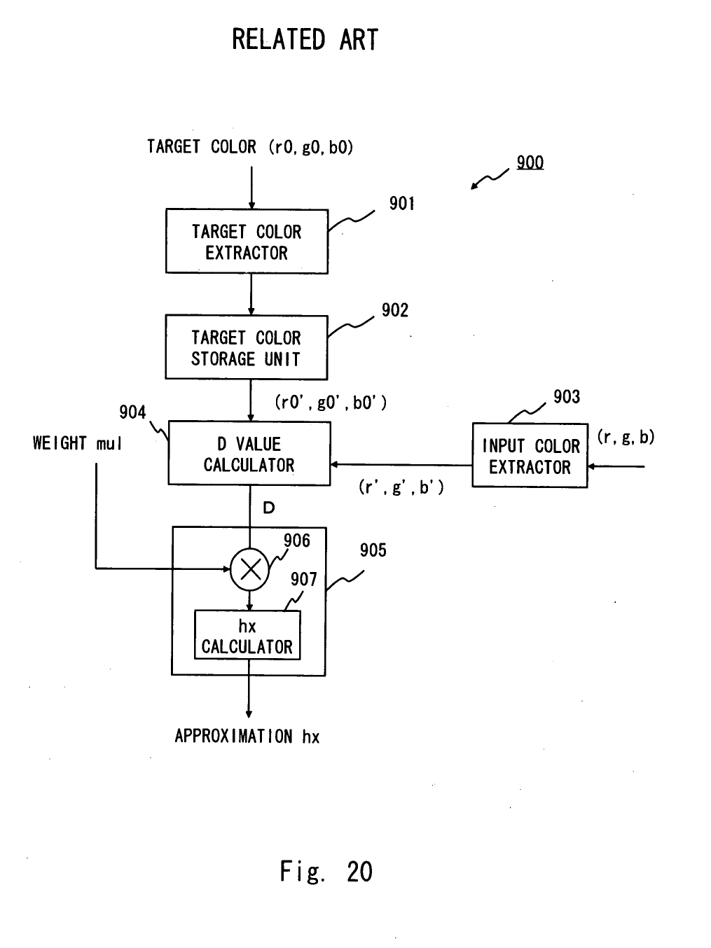

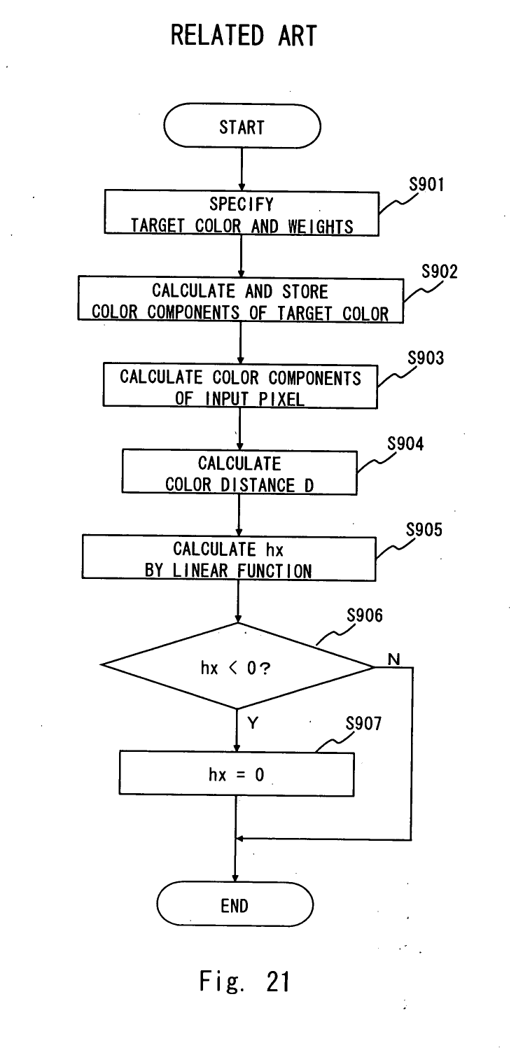

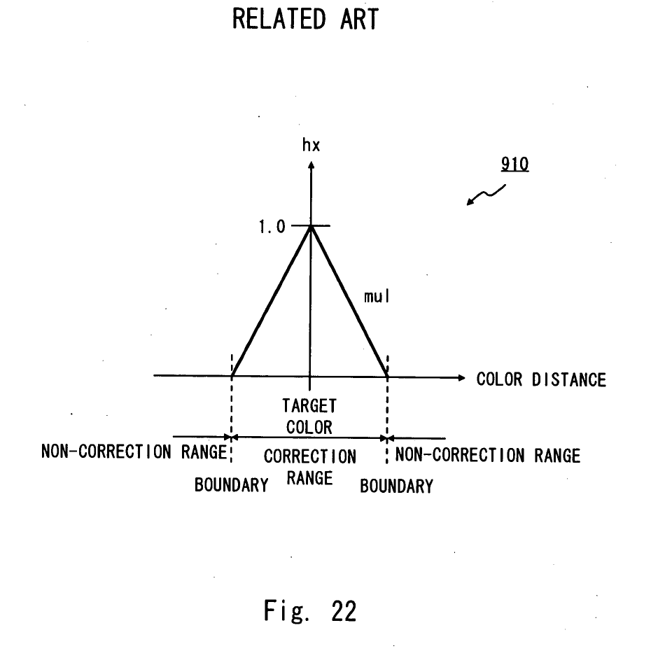

FIG. 19 is a view showing an example of a hardware configuration of a computer system to accomplish the color correction apparatus 100. This system includes for example a central processing unit (CPU) 501 and a storage unit 502. The CPU 501 and the storage unit 502 are connected to a hard disk drive (HDD) 503 via a bus, where the HDD 503 is an auxiliary storage unit. The system typically includes user interface hardware. As the user interface hardware, there are for example a pointing device (mouse, joy stick etc) for input, an input device 504 such as a keyboard, and a display device 505 such as a liquid crystal display for providing visual data to users. The storage device such as the HDD 503 provides an instruction to the CPU 501 or the like in corporation with an operation system to store a computer program for performing functions of the system. Specifically, the CPU 501 processes according to program deployed on the storage unit 502 and cooperates with other hardware configuration to form each block of the correction apparatus 100 including the approximation calculator 1. The approximation calculation process by the approximation calculator 1 and the color correction process by the color correction apparatus 100 are accomplished by certain programs being executed in the CPU 501. The system may be configured by a plurality of computers, not limited to a single computer.

It is apparent that the present invention is not limited to the above embodiment and it may be modified and changed without departing from the scope and spirit of the invention.

What is claimed is:

1. A color correction apparatus comprising:
a correction unit to correct a color of an input pixel having a color included in a particular region of a color space; and
a correction amount calculator to change an amount of the color correction in a nonlinear manner in an order of colors disposed from inside the particular region to a boundary.

2. The color correction apparatus according to claim 1, wherein the correction amount calculator gradually decreases the color correction amount from inside the particular region to the boundary, so that the correction amount decreases to 0 at the boundary.

3. The color correction apparatus according to claim 2, wherein the correction amount calculator comprises a decrease trend controller that controls the decrease trend of the color correction amount at least once.

4. The color correction apparatus according to claim 3, wherein the decrease trend controller controls an approximation indicating an approximation of the input pixel to a target color to be corrected to be in the decrease trend, and the correction amount calculator further comprises a correction amount processing unit that calculates the color correction amount according to the approximation.

5. The color correction apparatus according to claim 4, wherein the decrease trend controller controls the approximation to be in the decrease trend by a broken line function having at least two decrease trends.

6. The color correction apparatus according to claim 5, wherein the decrease trend controller selects either a first approximation obtained by a first linear function or a second approximation obtained by a second linear function.

7. The color correction apparatus according to claim 6, wherein the decrease trend controller selects a maximum value from the first and the second approximation calculated by Formula 1 and Formula 2 below,
hx_{—}a=1−mul*D Formula 1 (if hx_a<0 then hx_a=0)
hx_{—}b=limit−mul2*D Formula 2 (if hx_b<0 then hx_b=0)
wherein the mul and the mul2 are weight coefficients specifying the decrease trend, the limit is an approximation limit, the D is a distance between the input pixel and the target color in the color space, hx_a is the first approximation, and hx_b is the second approximation.

8. The color correction apparatus according to claim 4, wherein the decrease trend controller continuously suppresses the decrease trend of the approximation.

9. The color correction apparatus according to claim 8, wherein the decrease trend controller controls the approximation to be in the decrease trend by a multidimensional function.

10. The color correction apparatus according to claim 9, wherein the decrease trend controller calculates the approximation by Formula 3 below,
hx=((Range−|D|)²)/(Range²) Formula 3 (if |D|>Range then hx=0)
wherein the Range is a range of the particular region, the D is a distance between the input pixel and the target color in the color space, and the hx is the approximation.

11. The color correction apparatus according to claim 9, wherein the decrease trend controller calculates the approximation by Formula 4 below,
hx=(2*(Range−|D|)³)/(Range³)−(3*(Range−|D|)²/(Range²)+1 Formula 4 (if |D|>Range then hx=0)
wherein the Range is a range of the particular region, the D is a distance between the input pixel and the target color in the color space, and the hx is the approximation.

12. The color correction apparatus according to claim 8, wherein the decrease trend controller selects either a first approximation obtained by a first multidimensional function or a second approximation obtained by a second multidimensional function.

13. The color correction apparatus according to claim 12, wherein the decrease trend controller selects the first approximation calculated by Formula 5 below if |D|<=Pos, selects the second approximation calculated by Formula 6 below if |D|<=Range, and sets to 0 if |D|>Range,
hx_{—}p=−(|D|²)/(Range*Pos)+1 Formula 5
hx_{—}r=((Range−|D|)²)/(Range*(Range−Pos)) Formula 6
wherein 0<=Pos<=Range, and
the Range and the Pos are ranges of the particular region, the D is a distance between the input pixel and the target color in the color space, the hx_p is the first approximation, and the hx_r is the second approximation.

14. A method for color correction to correct a color of an input pixel having a color included in a particular region of a color space, the method comprises:
changing an amount of the color correction in a nonlinear manner in an order of colors disposed from inside the particular region to the boundary.

15. The method according to claim 14, wherein the color correction amount is gradually decreased from inside the particular region to the boundary, so that the correction amount decreases to 0 at the boundary.

16. The color correction method according to claim 15, wherein the decrease trend of the color correction amount is controlled for at least once.

17. A program product for executing a color correction process by a computer to correct a color of an input pixel having a color included in a particular region of a color space, the program product comprises:
changing an amount of the color correction in a nonlinear manner in an order of colors disposed from inside the particular region to the boundary.

18. The program product according to claim 17, wherein the color correction amount is gradually decreased from inside the particular region to the boundary, so that the correction amount decreases to 0 at the boundary.

19. The program product according to claim 18, wherein the decrease trend of the color correction amount is controlled for at least once.
